(19) United States
(12) Patent Application Publication
(10) Pub. No.: US 2026/0235660 A1
(43) Pub. Date: Aug. 13, 2026

(54) System for Testing Electronic Devices on the Move

(71) Applicant: Tu Nguyen, Southlake, TX (US)

(72) Inventor: Tu Nguyen, Southlake, TX (US)

(21) Appl. No.: 19/535,647

(22) Filed: Feb. 10, 2026

Related U.S. Application Data
(60) Provisional application No. 63/756,747, filed on Feb. 10, 2025.

(51) Int. Cl. G01R 31/28; G01N 21/17; G01N 21/84

(52) U.S. Cl. CPC G01R 31/2808; G01N 21/17; G01N 21/84; G01R 31/2803; G01N 2021/1765; G01N 2021/845; G01N 2201/12

(57) ABSTRACT

A testing conveyor for electronic devices is disclosed, comprising a carrier to which a device is connected. The carrier then performs all the required functional tests while the device is transported from the input to the output side of the conveyor. A cosmetic grading tunnel may also be included to evaluate the cosmetic condition of the device.

### CROSS-REFERENCE TO RELATED APPLICATIONS

The present application takes priority from Provisional App. No. 63/756,747, filed Feb. 10, 2025, which is incorporated herein by reference.

### BACKGROUND

There is a huge market for recycled and refurbished used electronic devices, including computers, laptops, tablets, or HINT (Home Internet) devices such as routers, modems, repeaters, and other similar devices, as well as computers, phones, tablets, Internet of Things connected devices, and so on. Prior to refurbishing or recycling such a device, it is necessary to test it to make sure it is functional and to ascertain its cosmetic condition.

In the prior art, this testing is accomplished by physically carrying the device from one testing station to another. For example, the device could be carried from receiving location to the first test station to test its radio emitter, then to another test station to test its battery, and so on. Then, after all the tests are completed, the device is then brought to an output location, packaged, and shipped. This is very labor-intensive and time-intensive, since the device has to be physically transported from one station to another and connected and disconnected tested device and test equipment each time it is tested. at each test station.

A need exists for a more streamlined system and method for testing electronic devices to remove the labor-intensive and time-intensive method.

### LIST OF FIGURES

FIG. 1 is an overview of an embodiment of the system of the present invention.

FIG. 2 is a view of an embodiment of a carrier of the present invention.

FIG. 3 is a view of an embodiment of a cosmetic grading tunnel of the present invention.

FIG. 4 is a view of an embodiment of the present invention.

FIG. 5 is a view of an embodiment of a charging station for the carriers of the present invention.

### DETAILED DESCRIPTION

For purposes of the present disclosure, a “device” or “device under test” is any electronic device that requires testing before it is packaged for resale. The device could be a computer, phone, Internet router, modem, or any other electronic device. “Testing” includes functional testing or cosmetic evaluation.

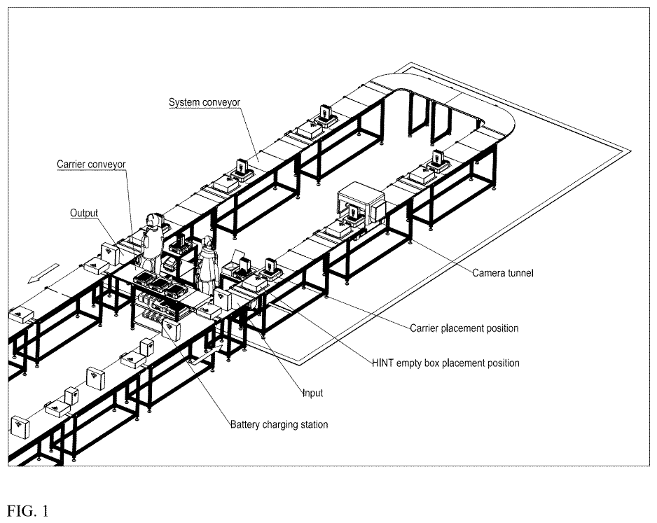

FIG. 1 shows an embodiment of the overall system of the present invention. A system conveyor is used to transport devices under test through the testing process. The devices are put on the system conveyor at the input location, and the empty box for each device is placed close to the device. Each device is connected to a carrier as will be discussed below. A camera tunnel is located at some point along the length of the system conveyor; the camera tunnel is used to evaluate the cosmetic condition of the device and of the box. The devices are transported from the input side to the output side of the conveyor; the functional testing is timed so that all the functional tests (including a RF test) conclude by the time the device reaches the output side. The device is then packaged and labeled appropriately, while the carrier is put on a carrier conveyor to be transported to a battery charging station.

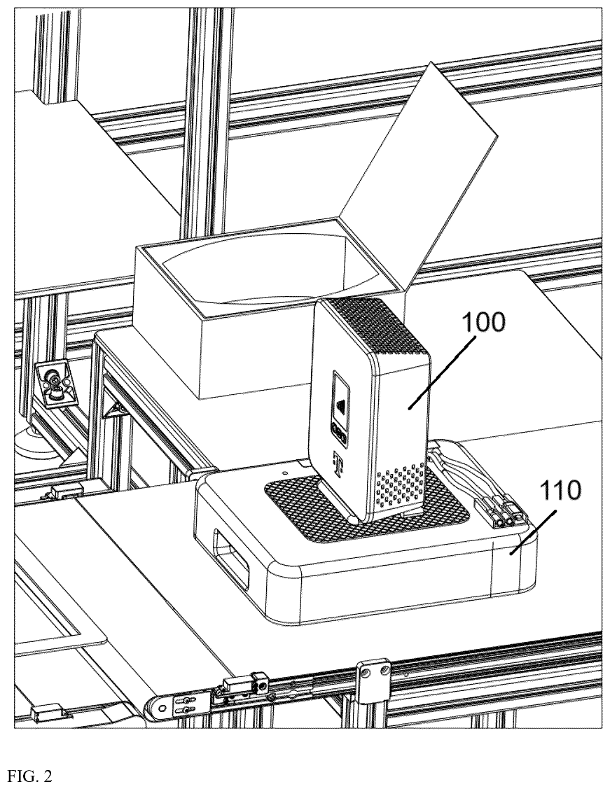

FIG. 2 shows a close-up view of a device 100 on a carrier 110. As shown, the carrier 110 is plugged into the device 100 and the device 100 is placed on top of the carrier 110 as shown. The carrier is a computing device that can communicate wirelessly with a server or with the cloud, connect with the device, and perform all the functional tests that are required. It comprises a battery that can provide it enough power to perform the required tests while the device is on the conveyor belt, while also powering the device. In an embodiment, the carrier may be powered via a wired connection, wireless charging, or any other power supply.

To test the device, the carrier first identifies the device and pairs with the device. Then, after identifying the device, it determines what functional tests are needed. In an embodiment, the carrier may also erase all the confidential personal information (CPI) data on the device. After determining what functional tests are needed, the carrier initiates the testing. The carrier may also update the firmware on the device as needed.

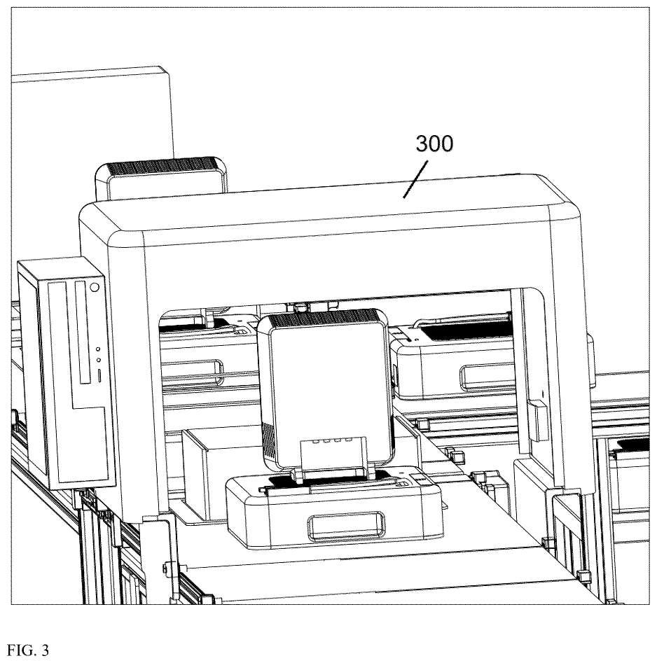

In an embodiment, the system may also evaluate the cosmetic condition of the device, which is important for consumer electronics. FIG. 3 shows a view of the cosmetic grading tunnel 300 of the present invention. At least one camera is located inside the cosmetic grading tunnel 300 and pointed at the device; in an embodiment, the cosmetic grading tunnel 300 could comprise 2 cameras, 3 cameras, or any other number. The cameras are preferably pointed in such a way as to provide images of each side of the device, to provide 5 images of 5 sides of the device (excluding the bottom side). The cameras inside the cosmetic grading tunnel 300 are preferably connected to a separate computing device that collects the camera data and uploads it to the cloud or to a local server. In an embodiment, the cosmetic grading tunnel 300 also comprises an RFID reader that identifies the carrier as it passes through the tunnel; since the carrier is paired with the device, that means that the cosmetic grading tunnel 300 can also identify the device.

As the carrier conducts the functional tests on the device, it collects test data. The test data collected by the carrier are preferably stored on the carrier until all the testing is completed. After the testing is completed, the carrier uploads all the test data to the cloud or to a local server for evaluation and recording. In an embodiment, the test data may be partially or completely processed by the carrier before being uploaded.

After the testing is completed, the carrier uploads all the test data camera and the images from the tunnel are also uploaded to the cloud or to a local server for evaluation and recording. In an embodiment, the test data may also be collected and evaluated on a local computing device to which all the carriers connect. In another embodiment, the carrier may perform some of the data processing and evaluation steps before uploading the data. The cloud or local server then generates a label and sends it to the printer.

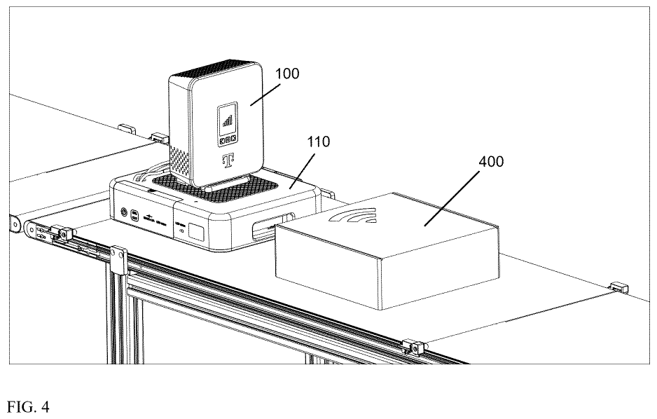

In many situations, to avoid waste, it is advisable to reuse the box that was originally used for the device. In an embodiment, the system of the present invention evaluates the cosmetic condition of the box as well as the device. In this embodiment, the box 400 is placed on the same conveyor as the carrier as shown in FIG. 4. The cosmetic grading tunnel 300 then is used to evaluate the box 400 and to determine whether its cosmetic condition is sufficient to reuse it to package the device.

In an embodiment, the system also comprises a printer. The printer is intended to print a label for the box. The printer preferably is connected to the cloud or to the local server so that it can receive label data and print it so that a label can be affixed to the box.

After the device reaches the output end of the conveyor and all the tests are completed, an operator removes the device from the carrier and disconnects all the connections, puts it into the box, prints the label, and performs any other necessary actions.

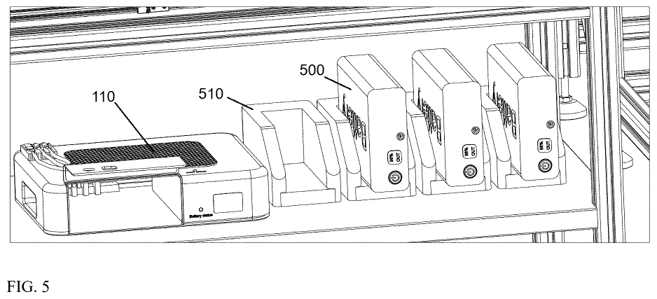

Since the carrier is preferably battery-powered, the battery will occasionally require recharging. A battery indicator is preferably provided on the carrier 110. FIG. 5 shows a charging station for carriers. If an operator determines that the carrier battery is low, they can remove the battery 500 from the carrier 110 and place it into a charger 510. The battery may be a lithium-ion battery or any other type of battery that can provide the required power. The battery preferably has at least enough power to power the carrier and the device for the duration of testing-for example, 5-10 minutes. In an embodiment, the battery can power the carrier and the device for longer, such as 2 hours, 10 hours, or 40 hours.

Exemplary embodiments are described above. It will be understood that the present invention encompasses other embodiments that form reasonable equivalents to the above described elements.

1. A system for testing electronic devices, comprising:
a. a system conveyor for transporting an electronic device through a testing process, comprising an input location and an output location;
b. a plurality of carriers located on the system conveyor, wherein each carrier is a computing device, comprising:
i. a processor and memory that are configured to perform at least one functional test on the electronic device;
ii. a device interface that connects the carrier to the electronic device and provides power to the electronic device;
iii. a communication interface for communicating with a server;
c. wherein each of the plurality of carriers is configured in such a way as to perform at least one functional test on the electronic device;
d. wherein each of the plurality of carriers and the system conveyor are configured in such a way that all of the at least one functional test conclude by the time the electronic device arrives at the output location.

2. The system of claim 1, wherein the carrier is configured to perform at least some of the following actions while the system conveyor is in motion:
a. identify an electronic device that is connected to it;
b. pair with the electronic device;
c. erase any confidential personal information on the electronic device;
d. determine what functional tests are required for the electronic device;
e. perform a Network connectivity and RF test;
f. upgrade OS or Firmware if needed;
g. perform functional tests on the electronic device;
h. store test data from the device's attributes and functional tests;
i. upload all collected data to a local and or cloud servers.

3. The system of claim 2, wherein the carrier is further configured to perform data processing on the test data prior to uploading it to a server.

4. The system of claim 2, wherein the carrier comprises the following:
a. an AI-based CPU;
b. a built-in rechargeable battery that can provide power to a carrier for a day or be used to test at least 40 electronic devices;
c. an RFID tag for identification;
d. a wireless communication interface to connect to the local and cloud server;
e. a device communication interface for communicating with and testing the electronic device, comprising at least one of the following: sensors, lidar, camera, wi-fi, Bluetooth.

5. The system of claim 2, wherein the carrier comprises a wired power connection and a wired communication connection to the electronic device.

6. The system of claim 2, wherein the carrier comprises a battery for providing power to the electronic device.

7. The system of claim 1, further comprising:
a. a cosmetic grading tunnel, wherein the cosmetic grading tunnel comprises at least one camera located in such a way as to take a photo of the electronic device while it is on the carrier and the carrier is on the system conveyor.

8. The system of claim 2, wherein the cosmetic grading tunnel comprises a plurality of cameras that can produce 5 images of the device from 5 sides.

9. The system of claim 2, wherein the at least one camera is connected to a separate computing device that collects the camera images and AI processing images to a cosmetic grade per predetermined cosmetic standard and uploads it to a server.

10. The system of claim 2, wherein the cosmetic grading tunnel further comprises an RFID reader, wherein the RFID reader identifies a carrier as it passes through the tunnel.
